(19) United States
(12) Patent Application Publication
(10) Pub. No.: US 2008/0157398 A1
(43) Pub. Date: Jul. 3, 2008

(54) Semiconductor device package having pseudo chips

(75) Inventors: Wen-Kun Yang, Hsin-Chu City (TW); Jui-Hsien Chang, Jhudong Township (TW); Chi-Chen Lee, Taipei City (TW); Wen-Ping Yang, Hsinchu City (TW)

Correspondence Address: BACON & THOMAS, PLLC, 625 SLATERS LANE, FOURTH FLOOR, ALEXANDRIA, VA, 22314, US

(73) Assignee: Advanced Chip Engineering Technology Inc., Hukou Township (TW)

(21) Appl. No.: 11/819,193

(22) Filed: Jun. 26, 2007

Related U.S. Application Data
(63) Continuation-in-part of application No. 11/648,688, filed on Jan. 3, 2007.

(51) Int. Cl. H01L 23/48

(52) U.S. Cl. 257/783; 257/E23.141; 257/E23.01

(57) ABSTRACT

The present invention provides a semiconductor device package having pseudo chips structure comprising a first substrate with die receiving through holes formed thereon; a first die having first bonding pads and a second die having second bonding pads disposed within the die receiving through holes, respectively; an adhesion material formed in the gap between the first and second die and sidewalls of the die receiving though holes of the first substrate; redistribution lines formed to couple the first contact pads formed on the first substrate to the first bonding pads and the second bonding pads, respectively; and a protection layer formed on the redistribution lines, the first die, the second die and the first substrate.

### CROSS-REFERENCE

The present application is a continue-in-part (CIP) application of a pending U.S. application Ser. No. 11/648,688, entitled “Wafer Level Package with Die Receiving Through-Hole and Method of the Same”, and filed on Jan. 3, 2007, which is incorporated herein by reference in its entirety.

### BACKGROUND OF THE INVENTION

1. Field of the Invention

This invention relates to a structure of semiconductor device package, and more particularly to a structure of semiconductor device package having pseudo chips function, thereby shrinking the package size and improving the yield and reliability.

2. Description of the Prior Art

In recent years, the high-technology electronics manufacturing industries launch more feature-packed and humanized electronic products. Rapid development of semiconductor technology has led to rapid progress of a reduction in size of semiconductor packages, the adoption of multi-pin, the adoption of fine pitch, the minimization of electronic components and the like.

Because conventional package technologies have to divide a dice on a wafer into respective dice and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip ball grid array (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dice). By wafer level packaging technology, we can produce die with extremely small dimensions and good electrical properties. Though the advantages of WLP technique mentioned above, some issues still exist influencing the acceptance of WLP technique. Traditionally, due to the package structure having multiple-chips is required, the sizes of the package structure increases with the numbers or total heights of multiple dice, so that the processes is more complex.

FIG. 1 illustrates the conventional package with stacked dice. The package structure 100 comprises a first die 120 having first bonding pads 116 formed thereon and a second die 122 having second bonding pads 118 formed therein, and the first die 120 and the second die 122 are formed on a first substrate 104 with first contact pads 114 formed therein. The package structure 100 further comprises a third die 124 having third bonding pads 112 formed under the first substrate 104, but over a second substrate 102 with second contact pads 110. Further, the third bonding pads 112 are connected to the second contact pads 110 by the bonding wires 126, the first contact pads 114 are connected to the second contact pads 110 through the bonding wires 128, the first bonding pads 116 and the second bonding pads 118 are respectively connected to the first contact pads 114 via the bonding wires 130 and 132. Then, the protection layer 145 is formed to cover the first die 120, the second die 122, the third die 124, and the solder bumps 150 are formed under the second substrate 102. Accordingly, the size of the package structure 100 is accumulated and equivalent to the total sizes of each material layer, and the processes for manufacturing the package structure becomes more and more complex and costly with the increasing chips.

In view of the aforementioned, what is required is a brand new structure having pseudo chips function to overcome the above drawback.

### SUMMARY OF THE INVENTION

The present invention will descript some preferred embodiments. However, it is appreciated that the present invention can extensively perform in other embodiments except for these detailed descriptions. The scope of the present invention is not limited to these embodiments and should be accorded the following claims.

One objective of the present invention is to provide a structure of semiconductor device package, which can provide a new structure having pseudo chips function.

Another objective of the present invention is to provide a structure of semiconductor device package, which can provide a small structure of a semiconductor device package (small foot print and thinner).

Still another objective of the present invention is to provide a structure of semiconductor device package, which can allow a better reliability.

Yet another objective of the present invention is to provide a structure of semiconductor device package, which can lower cost and higher yield rate.

The present invention provides a structure of semiconductor device package, comprising a first substrate with die receiving through holes formed therein; a first die having first bonding pads and a second die having second bonding pads disposed within the die receiving through holes, respectively; an adhesion material formed in the gap between the first and second die and sidewalls of the die receiving though holes of the first substrate; redistribution lines formed to couple the first contact pads formed on the first substrate to the first bonding pads and the second bonding pads, respectively; and a protection layer formed on the redistribution lines, the first die, the second die and the first substrate.

The present invention provides a structure of semiconductor device package, comprising a first substrate with first die receiving through holes formed therein; a first die having first bonding pads and a second die having second bonding pads disposed within the first die receiving through holes, respectively; a first adhesion material formed in the gap between the first and second die and sidewalls of the first die receiving though holes of the first substrate; redistribution lines formed to couple the first contact pads formed on the first substrate to the first bonding pads and the second bonding pads, respectively; a protection layer formed on the redistribution lines, the first die, the second die and the first substrate; a second substrate with second die receiving through holes and second contact pads and formed on an second attached material and under the first substrate; and a third die having third bonding pads disposed within the second die receiving through holes.

The present invention provides a structure a structure of semiconductor device package, comprising a first substrate with die receiving through holes formed therein; a first die having first bonding pads and a second die having second bonding pads disposed within the first die receiving through holes, respectively; a first adhesion material formed in the gap between the first and second die and sidewalls of the die receiving though holes of the first substrate; redistribution lines formed to couple the first contact pads formed on the first substrate to the first bonding pads and the second bonding pads; a protection layer formed on the redistribution lines, the first die, the second die and the first substrate; a third die having third bonding pads disposed under the first substrate; and a second substrate with second contact pads and circuit wires formed therein and formed under the third die.

### BRIEF DESCRIPTION OF THE DRAWINGS

The foregoing aspects and many of the attendant advantages of this invention will become more readily appreciated as the same becomes better understood by reference to the following detailed description, taken in conjunction with the accompanying drawings, wherein:

FIG. 1 illustrates a cross-section diagram of a structure of semiconductor device package according to the prior art;

FIG. 2 illustrates a top view diagram of a structure of semiconductor device package according to one embodiment of the present invention;

FIG. 3 illustrates a cross-section diagram of a structure of semiconductor device package according to one embodiment of the present invention;

FIG. 4 illustrates a cross-section diagram of a structure of semiconductor device package according to another embodiment of the present invention;

FIG. 5 illustrates a cross-section diagram of a structure of semiconductor device package according to another embodiment of the present invention;

FIG. 6 illustrates a cross-section diagram of a structure of semiconductor device package according to another embodiment of the present invention; and

FIG. 7 illustrates a cross-section diagram of a structure of semiconductor device package according to another embodiment of the present invention.

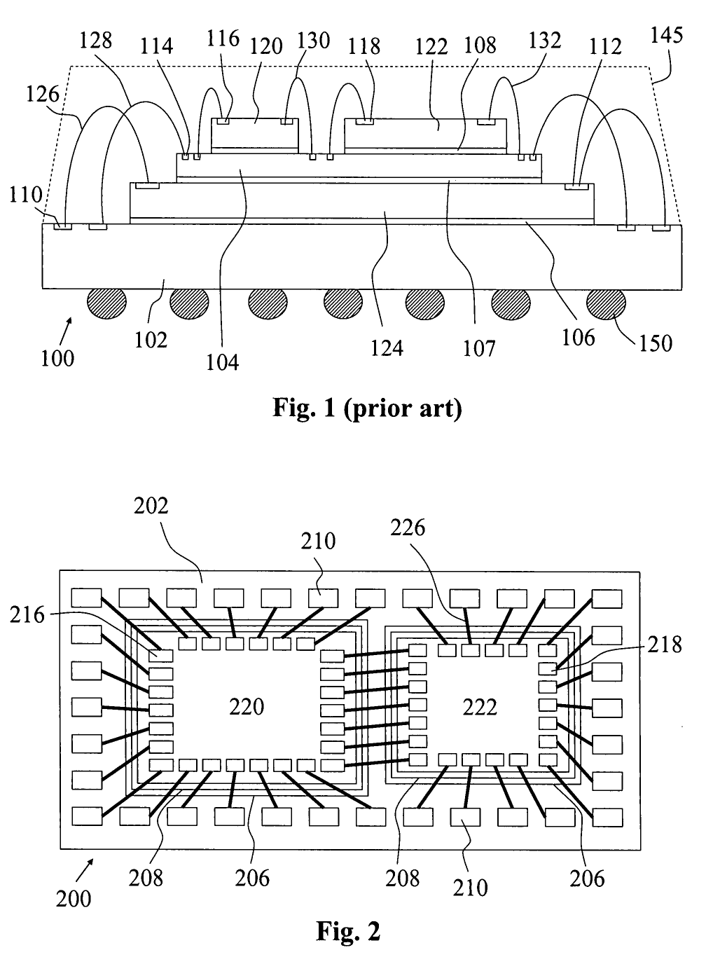

### DESCRIPTION OF THE PREFERRED EMBODIMENT

In the following description, numerous specific details are provided in order to give a through understanding of embodiments of the invention. Referring now to the following description wherein the description is for the purpose of illustrating the preferred embodiments of the present invention only, and not for the purpose of limiting the same. One skilled in the relevant art will recognize, however, that the invention may be practiced without one or more of the specific details, or with other methods, components, materials, etc.

According to an aspect of the present invention, the present invention provides the side-by-side structures of semiconductor device, as shown in FIGS. 2, 3, 4 and 5.

FIG. 2 illustrates a top view diagram of a structure of semiconductor device package 200 according to one embodiment of the present invention. The package 200 comprises a first substrate 202 having a first die 220 with the first bonding pads 216 and a second die 222 with the second bonding pads 218. The adhesion material 208 is respectively formed surrounding the edges of the first die 220 and the second die 222. The first substrate 202 has a plurality of first contact pads 210 surrounding the periphery of the first substrate 202. The redistribution lines (RDL) 226 are formed to electrically connect between the first contact pads 210 and the first bonding pads 216, between the first contact pads 210 and the second bonding pads 218, and between the first bonding pads 216 and the second bonding pads 218, respectively.

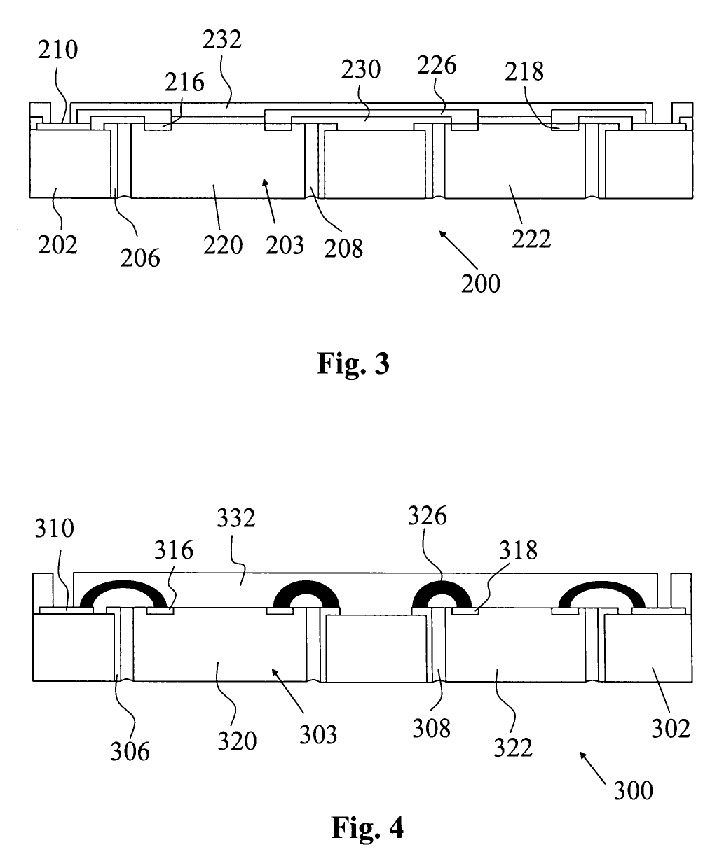

Referring to FIG. 3, it is a cross-section diagram of a structure of semiconductor device package 200 according to one embodiments of the present invention. In FIG. 3, the first substrate 202 has the first die receiving through holes 203 formed therein for receiving the first die 220 and the second die 222. The first die receiving through holes 203 are formed from the upper surface of the first substrate 202 through the first substrate 202 to the lower surface. The first die receiving through holes 203 are preformed within the first substrate 202. The adhesion material 208 is formed within the gaps between the edge of first and second dice 220, 222 and the sidewalls of the first die receiving through holes 203. The first contact pads 210 (for organic substrate) are formed on the upper surface of the first substrate 202.

Further, a dielectric layer 230 is formed on the first die 220, the second die 222 and the first substrate 202 to expose the surfaces of the first bonding pads 216, the second bonding pads 218 and the first contact pads 210. The redistribution lines (RDL) 226 are formed between the first bonding pads 216 and the second bonding pads 218, between the first contact pads 210 and the first bonding pads 216, and between the first contact pads 210 and the second bonding pads 218 for electrically connection with each other (the first contact pads 210 maybe formed with the redistribution lines (RDL) 226 at the same time). A protection layer 232 is formed on the first and second dice 220, 222, the dielectric layer 230 and the redistribution lines (RDL) 226 to expose the surfaces of the first contact pads 210. It is noted that the redistribution lines (RDL) 226 are invisible after the formation of the final attached material.

Optional, a metal or conductive layer 206 is coated on the sidewall of the first die receiving through holes 203, that is to say, the metal layer 206 is formed between the first and second dice 220 and 222 surrounding by the adhesion material 208 and the first substrate 202. It can improve the adhesion strength between die edge and sidewall of the first die receiving through holes 203 of the first substrate 202 by using some particular adhesion materials, especially for the rubber type adhesion materials.

The first die 220 and the second die 222 are respectively disposed within the first die receiving through holes 203 on the first substrate 202. As know, the first bonding pads 216 are formed within the upper surface of the first die 220, and the second bonding pads 218 are formed within the upper surface of the second die 222.

The protection layer 232 is employed to prevent the package from being damage by the external force during further packaging process, it maybe covered by the final attached material as the protection layer 232 after the final packaging process.

In one embodiment, the material of the first substrate 202 includes epoxy type FR5, FR4 or BT (Bismaleimide triazine epoxy). The material of the first substrate 202 also can be metal, alloy, glass, silicon, ceramic or print circuit board (PCB). The alloy further includes alloy 42 (42% N1-58% Fe) or Kovar (29% Ni-17% Co-54% Fe). Further, the alloy metal is preferably composed by alloy 42 that is a nickel iron alloy whose coefficient of expansion makes it suitable for joining to silicon chips in miniature electronic circuits and consists of nickel 42% and ferrous (iron) 58%. The alloy metal also can be composed by Kovar which consists of nickel 29%, cobalt 17% and ferrous (iron) 54%.

Preferably, the material of the first substrate 202 is organic substrate likes epoxy type FR5, BT, PCB with defined through holes or Cu alloy metal with pre-etching circuit. Preferably, the coefficient of thermal expansion (CTE) is the same as the one of the mother board (PCB), and then the present invention can provide a better reliability structure due to the CTE of the first substrate 202 is matching with the CTE of the PCB (or mother board) accordingly. Preferably, the organic substrate with high Glass transition temperature (Tg) are epoxy type FR5 or BT (Bismaleimide triazine) type substrate. The Cu alloy metal (CTE around 16) can be used also. The glass, ceramic, silicon can be used as the substrate. The adhesion material 208 is formed of silicone rubber elastic materials.

In one embodiment, the material of the adhesion material 208 include Siloxane polymer (SINR), WL5000, rubber, epoxy resin, liquid compound and polyimide (PI). The adhesion material 208 also can be included the metal material.

Alternatively, in another embodiment, the redistribution lines (RDL) 226 shown in FIG. 3 are the bonding wires 326 used for electrical connection, as shown in FIG. 4.

In FIG. 4, the package structure 300 comprises the substrate 302 having the first die 320 and the second die 322 formed within the pre-formed first die receiving through holes 303. The adhesion material 308 is formed into the gaps between the substrate 302 and the first and second dice 320 and 322. Optionally, the metal or conductive layer 306 is formed to fill the gaps between the substrate 302 and adhesion material 308. The contact pads 310 are respectively coupled to the first bonding pads 316 and the second bonding pads 318 by the bonding wires 326. The bonding wires 326 are further respectively coupled to the metal or conductive layer 306 and the first and the second bonding pads 316 and 318. Then, the protection layer 332 is formed on the first die 320, the second die 322 and the bonding wires 326 to expose the surfaces of the contact pads 310 for electrical connection.

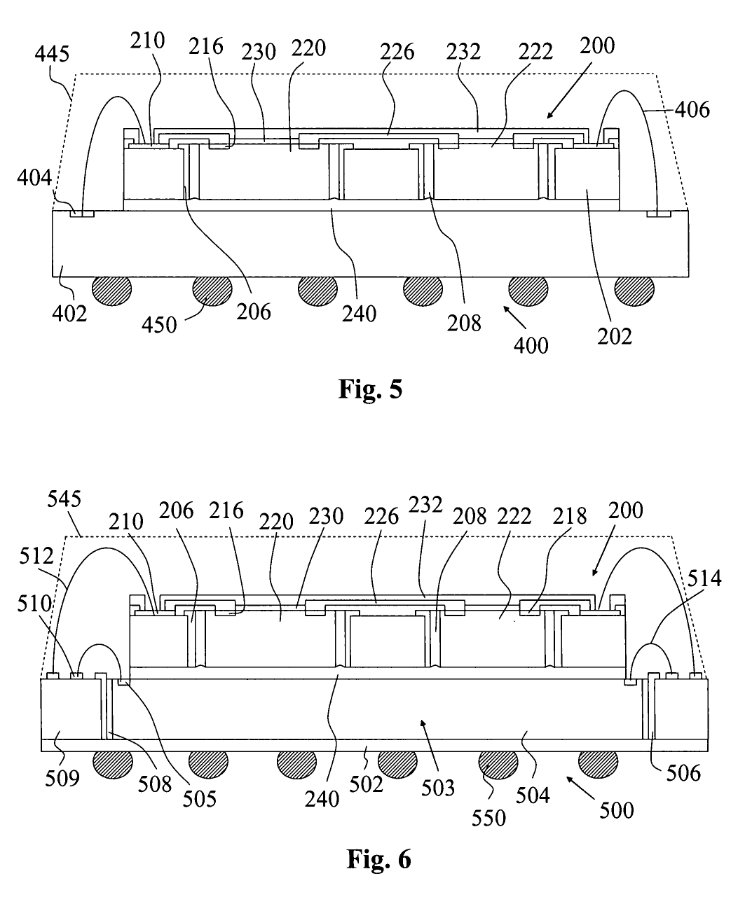

FIG. 5 illustrates a cross-section diagram of a package structure 400 of semiconductor device according to another embodiment of the present invention. It is noted that the certain descriptions regarding the similar elements are omitted to avoid obscuring the present invention.

In FIG. 5, the package structure 400 comprises the package structure 200, as shown in FIG. 3, formed on the second substrate 402 with the second contact pads 404 and circuit wiring formed therein. The package structure 200 is formed on an attached material 240, and then formed on the second substrate 402. The package structure 400 further comprises the bonding wires 406 coupled to the second contact pads 406 and the first contact pads 210 for electrical connection. In other words, the first contact pads 210 formed and surrounded on the edge areas of the first substrate 202 can be electrically coupled to the second contact pads 404 formed within the second substrate 402. The present invention further comprises the final protection material 445 formed to cover the package, and the final soldering material 450 is formed on the terminal metal pads on lower site of the second substrate 402.

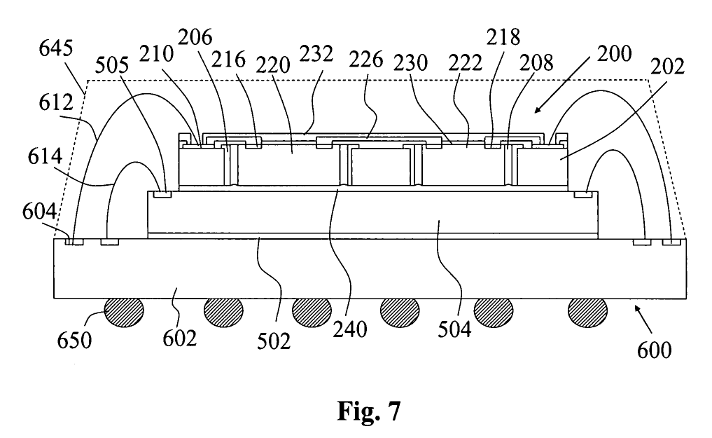

According to the aspect of the present invention, the present invention further provides the stacking structures of semiconductor device, as shown in FIGS. 6 and 7. The embodiment further includes pseudo chips formed within the structure over the second substrate. The pseudo chips act as a single chip in the present invention, it can avoid the bonding wires too long or too short issue due to the chip size difference in the structure of chip stacking package, the pseudo chips not only can reduce the package body thickness, foot print but also simplify the wire bonding process to increase the packaging yield and quality.

Refer to FIG. 6, it illustrates a cross-section diagram of a package structure 500 of semiconductor device according to another embodiment of the present invention. The package structure 500 comprises the package structure 200, as shown in FIG. 3, formed on the second substrate 509 with the second contact pads 510 formed thereon. Further, the second substrate 509 has the pre-formed second die receiving holes 503 to receive the third die 504 having a plurality of third bonding pads 505 formed thereon. The attached material 502 is formed under the third die 504 and the second substrate 402, and the adhesion layer 508 is filled the sidewalls between the third die 504 and the second substrate 509. Optionally, the metal or conductive layer 506 is formed in the gaps between the second substrate 402 and the adhesion layer 508 to act as inter-connecting through hole to couple the signal from the upper layer of the second substrate 509 to the lower layer of the second substrate 509.

In FIG. 6, the package structure 500 further includes a plurality of bonding wires 512 to couple the second contact pads 510 and the first contact pads 512, and a plurality of bonding wires 514 coupled the second contact pads 510 and the third bonding pads 505. The final protection material 545 is formed to cover the package, and the final soldering material 550 is formed on the terminal metal pads on lower site of the second substrate 509. It is also noted that the certain descriptions regarding the similar elements are omitted to avoid obscuring the present invention.

Refer to FIG. 7, it illustrates a cross-section diagram of a package structure 600 of semiconductor device according to another embodiment of the present invention. The package structure 600 comprises the package structure 200, as shown in FIG. 3, formed on the third die 504 having the third bonding pads 505. The third die 504 is formed on the attached material 502, and the third die 504 is formed on the second substrate 602 with a plurality of second contact pads 604 and circuit wires formed thereon. In FIG. 7, the package structure 600 further includes a plurality of bonding wires 612 coupled to the second contact pads 604 and the first contact pads 210, and a plurality of bonding wires 614 coupled to the second contact pads 604 and the third bonding pads 505. The final protection material 645 is formed to cover the package, and the final soldering material 650 is formed on the terminal metal pads on lower site of the second substrate 602.

Optionally, a metal film (or layer) (not shown) can be sputtered or plated on the back side of the first, second and third dice 220, 222 and 504 for better thermal management inquiry.

In the specification, it is appreciated that the certain descriptions regarding the similar elements are omitted to avoid obscuring the present invention. It is noted that the material and the arrangement of the structure are illustrated to describe but not to limit the present invention. The material and the arrangement of the structure can be modified according to the requirements of different conductions.

According to the aspect of the present invention, the present invention provides a structure of semiconductor device having pseudo-chips that provides a structure of thin package. The package (pseudo chips) size can be adjustable according to the sizes of the multi-chips. Further, the present invention provides a good solution for low pin count device due to the peripheral type format. The present invention provides a simple package structure which can improve the reliability and yield. Moreover, the present invention further provides a new structure that has pseudo-chips to act as chip function and omit a substrate layer in the prior art, and can minimize the size of chip scale package structure and reduce the costs due to the lower cost material. Therefore, the thin chip scale package structure disclosed by the present invention can provide unexpected effect than prior art, and solve the problems of prior art. The structure may apply to wafer or panel industry and also can be applied and modified to other related applications.

As will be understood by a person skilled in the art, the foregoing preferred embodiments of the present invention are illustrative of the present invention, rather than limiting the present invention. Having described the invention in connection with a preferred embodiment, modification will suggest itself to those skilled in the art. Thus, the invention is not to be limited by this embodiment. Rather, the invention is intended to cover various modifications and similar arrangements included within the spirit and scope of the appended claims, the scope of which should be accorded the broadest interpretation so as to encompass all such modifications and similar structures.

What is claimed is:

1. A structure of semiconductor device package, comprising:
a first substrate with die receiving through holes;
a first die having first bonding pads and a second die having second bonding pads disposed within said die receiving through holes, respectively;
an adhesion material formed in the gaps between said first and second die and sidewalls of said die receiving though holes of said first substrate; and
redistribution lines formed to couple first contact pads formed on said first substrate to said first bonding pads and said second bonding pads, respectively.

2. The structure in claim 1, further comprising a pseudo chip formed under said first substrate.

3. The structure in claim 1, further comprising a dielectric layer formed under said redistribution lines.

4. The structure in claim 1, further comprising a protection layer formed on said redistribution lines, said first die, said second die and said first substrate, and expose the surfaces of said first contact pads.

5. The structure in claim 1, further comprising a metal or conductive layer formed on sidewalls of said die receiving through holes of said first substrate.

6. The structure in claim 1, wherein said redistribution lines are bonding wires.

7. The structure in claim 1, further comprising a second substrate having second contact pads and circuit wires formed therein.

8. The structure in claim 7, wherein said second contact pads are coupled to said first contact pads by a plurality of bonding wires.

9. The structure in claim 7, further comprising an attached material formed surrounding said first substrate and said second substrate.

10. The structure in claim 7, further comprising the soldering metal formed the lower site of said second substrate as terminal pins of package.

11. The structure in claim 1, wherein material of said first and second substrate includes epoxy type FR5, FR4, BT (Bismaleimide triazine), metal, alloy, glass, silicon, ceramic or print circuit board (PCB).

12. The structure in claim 1, wherein material of said adhesion material include Siloxane polymer (SINR), WL5000, rubber, epoxy resin, liquid compound and polyimide (PI).

13. A structure of semiconductor device package, comprising:
a first substrate with first die receiving through holes;
a first die having first bonding pads and a second die having second bonding pads disposed within said first die receiving through holes, respectively;
a first adhesion material formed in the gap between said first and second die and sidewalls of said first die receiving though holes of said first substrate;
redistribution lines formed to couple contact pads formed on said first substrate to said first bonding pads and said second bonding pads, respectively;
a protection layer formed on said redistribution lines, said first die, said second die and said first substrate;
a second substrate with second die receiving through holes and second contact pads, and formed on an second attached material and under said first substrate; and
a third die having third bonding pads disposed within said second die receiving through holes.

14. The structure in claim 13, further comprising a plurality of bonding wires coupled to said first contact pads and said second contact pads, and coupled to said third bonding pads and said second contact pads, respectively.

15. The structure in claim 13, further comprising a second adhesion material formed the gap between said third die and said second substrate.

16. The structure in claim 13, further comprising a metal or conductive layer formed on side walls of said second die receiving through holes of said second substrate

17. The structure in claim 13, wherein material of said first and second substrate includes epoxy type FR5, FR4, BT (Bismaleimide triazine), metal, alloy, glass, silicon, ceramic or print circuit board (PCB).

18. The structure in claim 13, wherein material of said adhesion material include Siloxane polymer (SINR), WL5000, rubber, epoxy resin, liquid compound and polyimide (PI).

19. A structure of semiconductor device package, comprising:
a first substrate with die receiving through holes;
a first die having first bonding pads and a second die having second bonding pads disposed within said die receiving through holes, respectively;
a first adhesion material formed in the gap between said first and second die and sidewalls of said die receiving though holes of said first substrate;
redistribution lines formed to couple first contact pads formed on said first substrate to said first bonding pads and said second bonding pads;
a protection layer formed on said redistribution lines, said first die, said second die and said first substrate;
a third die having third bonding pads disposed under said first substrate; and
a second substrate with second contact pads and circuit wiring formed therein and formed under said third die.

20. The structure in claim 19, further comprising bonding wires coupled to said first contact pads and said second contact pads, and coupled to said third bonding pads and said second contact pads, respectively.

21. The structure in claim 19, further comprising a second adhesion material formed between said first substrate and said third die, and between said third die and said second substrate, respectively.

22. The structure in claim 19, wherein material of said first and second substrate includes epoxy type FR5, FR4, BT (Bismaleimide triazine), metal, alloy, glass, silicon, ceramic or print circuit board (PCB).

23. The structure in claim 19, wherein material of said adhesion material include Siloxane polymer (SINR), WL5000, rubber, epoxy resin, liquid compound and polyimide (PI).
